(19) United States
(12) Patent Application Publication
(10) Pub. No.: US 2007/0057682 A1
(43) Pub. Date: Mar. 15, 2007

(54) Signal probe and probe assembly

(76) Inventor: Michael T. McTigue, Colorado Springs, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/227,943

(22) Filed: Sep. 15, 2005

(51) Int. Cl. G01R 31/02

(52) U.S. Cl. 324/754

(57) ABSTRACT

A probe includes a probe head adapted to connect to and disconnect from a target. An apparatus includes a plurality of connection assemblies over a target.

### Background

The evaluation and debugging of high-speed digital circuits and systems often require measurement and display of signal waveforms. Often, these measurements are made using test equipment such as a logic analyzer, an oscilloscope, or a spectrum analyzer. A portion of a signal from the circuit or system under test (often referred to as the target) is provided to the test equipment via a probe assembly.

Probe assemblies often comprise two parts. The first part is known as the probe head, which includes the probe tip and a cable (transmission line). The probe tip makes electrical contact with the electronics under test, which are often collectively referred to as the target. The second part of the probe assembly is known as the probe amp. The probe amp includes a pod, a main cable and an amplifier. The pod may or may not include electronics and completes the connection from the target to the test equipment.

As target electronics become more complex, the density of the circuits increases. The increased complexity of target electronics often requires multiple probe sites on the target board. One way to meet this need is to populate a target circuit board with multiple probe heads. As testing is desired at a particular location on the target, the probe amp is connected to the probe head and measurements are made. Unfortunately, probe heads are rather expensive, making this option unattractive.

There is a need for a signal probe and probe assembly that overcomes at least the shortcomings described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified schematic diagram of a test apparatus in accordance with an example embodiment.

FIG. 2A is a top view of a probe head in accordance with an example embodiment.

FIG. 2B is a top view of a connection accessory in accordance with an example embodiment.

FIG. 2C is a top view of a connection accessory disposed over a locking feature of a zero insertion force (ZIF) connector of the probe head in accordance with an example embodiment.

FIG. 2D is a top view of the connection accessory mated with the ZIF connector.

FIG. 3 is a simplified schematic diagram of a target circuit board (target board) including a plurality of connection accessories in accordance with an example embodiment.

### DETAILED DESCRIPTION

In the following detailed description, for purposes of explanation and not limitation, specific details are set forth in order to provide a thorough understanding of example embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

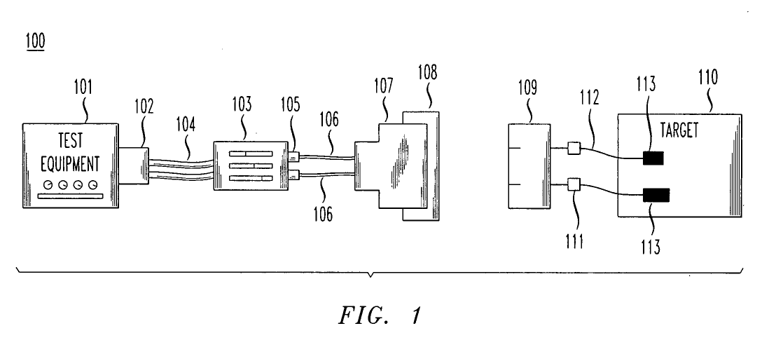

FIG. 1 is a simplified schematic diagram of a test apparatus 100 in accordance with an example embodiment. The test apparatus 100 includes test equipment 101, which may be an oscilloscope, a logic analyzer, a spectrum analyzer or similar device. A pod 102 is connected to the test equipment and to an amplifier 103 by a cable(s) 104. The cables 104 may be one or more suitable transmission lines, including but not limited to coaxial transmission lines and ribbon coaxial transmission lines. The pod 102 may include electronic components and circuits, passive and active electronic components, or a combination thereof.

As used herein, the term ‘probe amp’ refers collectively to the pod 102, the amplifier 103 and the cables 104. In a specific embodiment, the pod 102 and the amplifier 103 may be of the type provided in the InfiniMax® Probe System offered by Agilent Technologies, Inc. Further details of this probe system is disclosed in U.S. Pat. No. 6,704,670 to M. McTigue, assigned to the present assignee and specifically incorporated herein by reference. Alternatively, the pod 102 and amplifier 103 may be a pod or amplifier, or both, or commonly that are used in signal probing applications, including high frequency signal probing applications.

Beneficially, the cable 104 is relatively flexible so that when moved, the cable 104 does not move the probe amp where the probe head is connected to the target. In this manner, an appreciable force is not transferred to the probe head, which is rather delicate. Furthermore, the probe amp is usefully fairly flat in one dimension so it can be placed “in-situ” in a target system having circuit boards nominally spaced at approximately 0.5 in apart.

The amplifier 103 is connected to signal transmission lines 106 via connectors 105. The connectors 105 may be Gilbert push-on (GPO), Omni-Spectra subminiature push-on (OSMP, SMP) or other suitable connector. The connectors 105 connect signal transmission lines 106 to a zero insertion force (ZIF) electrical connector 107. The transmission lines 106 are illustratively coaxial cable transmission lines suitable for high-frequency signal transmission and for use in probing applications. In a specific embodiment, the coaxial transmission lines 106 include a braided center conductor a solid fluorinated ethylene propylene (FEP) dielectric, a braided ground shield, and a polyvinyl chloride (PVC) jacket; and can be terminated into GPO or SMP connectors. In addition, the characteristic impedance of the transmission lines is illustratively 50.0Ω±1.5Ω.

The ZIF electrical connector 107 connects the probe head to a connection accessory 109 that is connected to a target 110. As described in further detail herein, the ZIF connector includes a locking/unlocking feature 108 that facilitates the ZIF connection and locking of the ZIF electrical connector 107 to a connection accessory 109; and the ZIF disconnection of the ZIF connector 107 to the connection accessory 109.

The connection of the connection accessory 109 to the target 110 may be by known soldering or other known connection methods. Illustratively, the connection accessory 109 is connected to the contact points 113 (e.g., circuit lines) on the target 110 by electrical conductors 112 having damping elements 111 between the connection accessory 109 and the target 110. In a specific embodiment, the conductors 111 are coaxial cables and the damping elements 111 are resistors. In another embodiment, the damping elements 111 may be located on the connection accessory 109 with the electrical conductors 111 again providing the connection between the target 110 and the connection accessory.

As described in further detail herein, a plurality of connection accessories 109 may be distributed over the target at sites where testing is desired. The ZIF electrical connector 107 allows for ready, convenient connection and disconnection of the probe head to the connection accessories 109 in a manner that reduces, if not substantially eliminates, the likelihood of disconnection of the connection accessories 109 from the target 110.

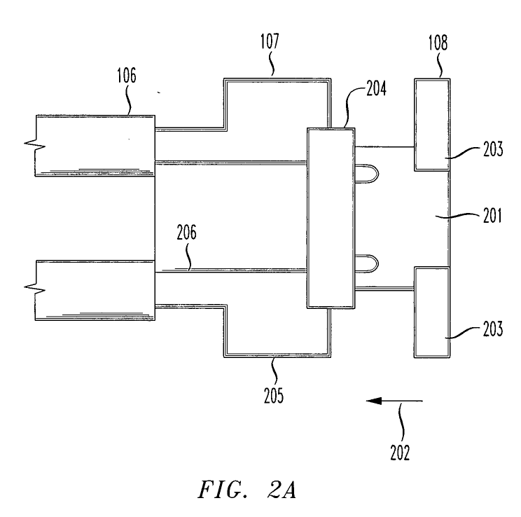

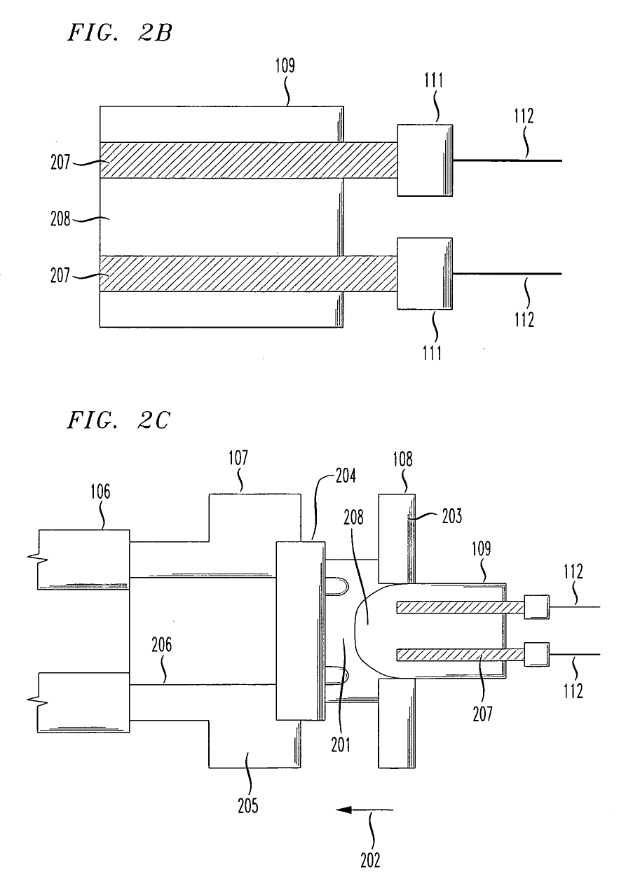

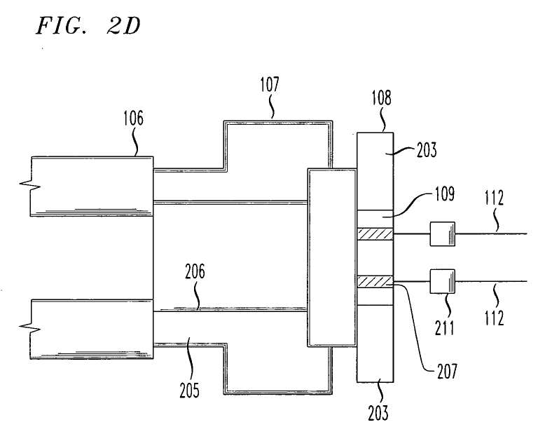

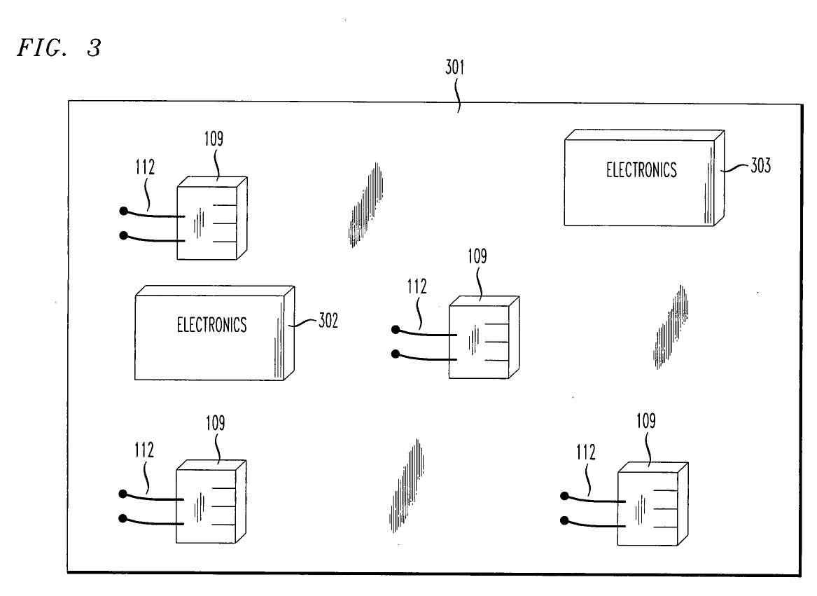

FIG. 2A is an enlarged view of a portion of the probe head including the ZIF connector 107, the locking feature 108 and the transmission lines 106. The locking feature 108 includes a base 201 that is adapted to receive the connection assembly 109. Moreover, the locking feature 108 includes ridges 203, which are adapted to engage the connection assembly 109. Upon movement of the locking feature 108 by engaging the ridges 203 with a tool (not shown) or manually, the locking feature 108 slides into position and thus moves the connection accessory 109 in direction 202 and into engagement with electrical contacts in a housing 204 of the ZIF connector 107. The ZIF connector 107 also includes a connection interface 205 that connects the contacts within the housing 204 with the transmission lines 106 via traces 206. The connection interface 205 may be one of a variety of structures adapted for high frequency signal transmission. For example, the connection interface 205 may comprise known flexible circuit boards and microstrip transmission line structures.

In the present embodiment, the locking feature is known as a slide-lock. The contacts within the housing 204 are in an ‘open’ position with the locking feature 108 withdrawn from the housing as shown in FIG. 2A. Upon movement of the locking feature 108 in direction 202, the contacts are drawn into contact with the base 201 by the locking feature 108 and thus the connection accessory 109. Because the contacts in the housing 204 are in an open position during the movement of the connection accessory 109 into the housing, little force is required to move the connection accessory into position of connection with the probe head. When the locking feature 108 is in the ‘locked position’ (i.e., moved into the housing 204 in its final position), the contacts are drawn down by the locking feature 108 and frictionally engage the contacts of the connection accessory 109. Similarly, as the locking feature 108 is moved out of the locked position (i.e., in the direction opposite of direction 202), the contacts in the housing are disengaged by the locking feature 108 from the contacts of the connection accessory 109, facilitating removal of the connection accessory with inappreciable force.

In a specific embodiment, the ZIF connector housing 104 including the locking/unlocking feature 108 is a ZIF Slide-Locking Type (0.5 mm-pitch) XF2L connector sold by Omron Corporation, Tokyo, Japan. Notably, other types of ZIF connectors may be used to connect/disconnect the connection accessory 109 with the probe head. For example, ZIF connectors with a back-lock adapted to provide connections between circuit boards may also be used. Alternatively, flexible printed circuit ZIF connectors widely used in electronic applications may be used in the ZIF connector 107.

FIG. 2B is an enlarged top view of the connection accessory 109 in accordance with an example embodiment. The connection accessory 109 includes contacts 207 disposed over a substrate 208. The substrate 208 may be a dielectric material suitable for high frequency signal transmission. For example, the substrate 208 may be the dielectric of signal transmission lines with the contacts 207 on one side of the substrate 208 functioning as the transmission lines and a ground plane (not shown) disposed on the other side of the substrate 208. In a specific embodiment, the substrate 208 is a printed circuit board (PCB) and the contacts 207 are electrical traces on the board.

The PCB used for the substrate 208 of the connection accessory 109 may be comprised of one of a variety of known dielectric materials. Typically, it is useful for the dielectric material to have a relatively low dielectric constant, with low dielectric loss. Known printed circuit board dielectric FR4 may be used provided the dielectric loss is within reasonable limits. In addition, thick-film dielectric substrates, or thin-film dielectric substrates may also be used, again provided the dielectric constant and loss are within limits. In general, the dielectric constant of the material chosen for the connection is less than approximately 7.0. In a specific embodiment, the dielectric constant is approximately 4.55. Notably, because the length of signal transmission across the connection is relatively small, dielectric loss is normally not a significant consideration. However, if a noticeable reduction in the amplitude of the signal were apparent, another dielectric material with more acceptable dielectric loss may need to be used for the dielectric material of the substrate 208.

In the presently described embodiment, two contacts 207 are shown. However, more or fewer contacts on the connection accessory 109 are contemplated. Furthermore, in certain embodiments, one of the contacts 207 may be a signal contact of a signal transmission line, and an adjacent contact on the connection accessory 109 may be a ground contact. Multiple signal/ground pairs may be disposed on the connection accessory 109 for connections to coaxial transmission lines that connect the connection accessory 109 and the target 110.

As noted previously, the ZIF connector 107 allows for the connection and disconnection of the probe head to the target 110 while substantially preventing damaging the connection of the connection assembly 109 to the target 110. In addition, the connections (e.g., solder joint) between the connection accessory 109 and the target are rather delicate due to the small feature sizes (e.g., electrical conductors 112). In particular, during use a rather large force may be applied to the probe head inadvertently. In known testing devices, this may result in the destruction of the solder joint to the probe or damage to a via on the target board, or both. However, because the connection between the probe head and the connection accessory 109 is via the ZIF connector 107, the connection accessory 109 will disengage from the probe head with little force and thereby protect the connection solder joints and vias. Therefore, the use of the ZIF connector 107 is exceedingly useful in preventing the damage to the target and disconnection of or damage to the connection of the connection accessory 109 to the target 110. In addition, the ZIF connector 107 is adapted to engage the connection accessory 109 without exerting an appreciable force on the electrical conductors 112 without supporting on the connection accessory 109. This allows the user to readily engage and disengage the probe head to the target without significant dexterity.

In many cases, the path for spaces on a printed circuit board of a target (target board) is on the order of approximately 0.040 in. Moreover, it is often useful to provide a large number of connections to the target, thereby requiring a plurality of connection accessories 109 in rather close proximity to one another. This size is usually dictated by the targets on the target board. Connection to vias on the target board at 0.025 in. spacing or less may be realized with the connection accessory 109. Moreover, connection to circuit traces on the target board having a width and spacing of approximately 0.050 in. or less may also be realized with the connection accessory 109.

In order to make connection to target board with feature size and spacing such as those noted above, the electrical conductors 112 are on the order of 0.050 in. These factors contribute to the need for the electrical conductors 112 to be rather small and correspondingly fragile. In a specific embodiment, the electrical conductors 112 are nickel wire, which are durable and have a relatively low heat conductivity. Alternatively a 1/7 copper/nickel wire may be used. This allows the probe head or connection accessory 109 to be soldered into the target system without un-soldering anything on the probe tip or connection accessory. In addition, the electrical conductors 112 may be as described in U.S. Pat. No. 6,864,694 to M. McTigue, assigned to the present assignee and specifically incorporated herein by reference.

FIG. 2C is an enlarged view of the probe head in pre-engagement with the connection accessory 109 in accordance with an example embodiment. As noted previously, the connection accessory is disposed over the base 201. The ridges 108 are then engaged by a tool (not shown) or manually to move the locking feature 108 and the connection accessory 109 in the direction 202. The movement of the connection accessory 109 into the housing 204 is by zero insertion force as described previously. Once the locking feature is in a locked position, the contacts of the ZIF connector 107 engage the contacts 207 of the connection accessory 109, thereby completing the electrical connection of the probe to the target. Once testing is complete, the ZIF connector 107 and the connection accessory 109 are disengaged by moving the locking feature 108 in the direction opposite to direction 202, again with a tool or manually.

FIG. 2D is an enlarged top view of the probe head connected to the connection feature and locked into position. In this position, the locking feature 108 is in the locked position, with the contacts of the ZIF connector 107 engaged with the contacts 207 of the connection accessory.

FIG. 3 is a simplified schematic diagram of a target board 301 in accordance with an example embodiment. The target board 301 may be a board on a target electronic device such as target 110. The target board 301 includes electronic components and modules (shown as electronics 302, 303) disposed thereover, as well as circuit traces and transmission lines (not shown). A plurality of connection accessories 109 are populated over the target board 301 and extend above the surface of the target board. For example, the connection accessories may be connected by electrical conductors 112 to sites on the target board dedicated for testing. The conductors are normally soldered as described previously. It is emphasized that while only one target board is shown, the target 110 may include a plurality of target boards. It is contemplated that each of the plurality target of target boards includes the electronics 302, 303 and connection accessories 109.

During testing a probe head engages a selected connection accessory 109 as described previously and testing is carried out. Upon completion of the test, the probe head is disengaged from the connection accessory 109 and used in the next test at another connection accessory 109. In this manner, a plurality of tests may be carried out at a plurality of locations across a target board using one probe head and a plurality of relatively inexpensive connection accessories 109. Because the connection and disconnection of the probe head is via zero insertion force connection, the connection is easily implemented and likely does not result in disconnection of the electrical conductors 112. In particular, because the electrical conductors 112 absorb the brunt of any force applied to the connection assembly 109, it is beneficial to limit the force applied due to the delicate nature of the conductors 112. This is readily achieved via the probe head of the example embodiments. Moreover, in the event that one of the connections is damaged, because the connection accessory 109 is relatively inexpensive a new connection may be made relatively inexpensively. For example, either the electrical conductors on the current connection accessory 109 can be re-soldered to the target if the connection accessory is still serviceable, or a new connection accessory 109 can be used.

In accordance with illustrative embodiments described, a probe is adapted to connect to a target via a ZIF connection. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A probe assembly, comprising:
a probe head having a probe tip, wherein the probe tip includes a zero insertion force (ZIF) electrical connector.

2. A probe assembly as recited in claim 1, further comprising a probe amp having an amplifier and at least one electrical cable adapted to connect the probe amp to test equipment.

3. A probe assembly as recited in claim 1, further comprising a connection accessory adapted to mate with the ZIF electrical connector.

4. A probe assembly as recited in claim 3, wherein the connection accessory is electrically connected to a target board.

5. A probe assembly as recited in claim 1, wherein the ZIF electrical connector further comprises a locking feature.

6. A probe assembly as recited in claim 2, wherein the probe head further comprises at least one signal transmission line.

7. A probe assembly as recited in claim 6, wherein the at least one signal transmission line is connected to the probe amp.

8. A probe assembly as recited in claim 5, wherein the locking feature further comprises at least one ridge adapted to move the locking feature.

9. An apparatus, comprising:
a probe head having a probe tip, wherein the probe tip includes a zero insertion force (ZIF) electrical connector;
a target; and
a plurality of connection accessories electrically connected to the target.

10. An apparatus as recited in claim 9, further comprising a probe amp having an amplifier and at least one electrical cable adapted to connect the probe amp to test equipment.

11. An apparatus as recited in claim 9, further comprising a testing apparatus.

12. An apparatus as recited in claim 11, wherein the testing apparatus is an oscilloscope.

13. An apparatus as recited in claim 11, wherein the testing apparatus is a logic analyzer.

14. An apparatus as recited in claim 9, wherein the ZIF electrical connector further comprises a locking feature.

15. An apparatus as recited in claim 10, wherein the probe head further comprises at least one signal transmission line.

16. An apparatus as recited in claim 10, wherein the at least one signal transmission line is connected to the probe amp.

17. An apparatus as recited in claim 9, wherein the locking feature further comprises at least one ridge adapted move the locking feature.

18. An apparatus as recited in claim 9, wherein the target includes at least one target circuit board and each of the plurality of connection accessories is connected to a contact point on the target circuit board.

19. An apparatus as recited in claim 18, wherein each of the connection accessories comprises an electrical conductor connecting a respective contact on the connection accessory to the contact point.

20. An apparatus as recited in claim 18, wherein each of the electrical conductors includes a damping element.
